(19) United States
(12) Patent Application Publication
(10) Pub. No.: US 2007/0152723 A1
(43) Pub. Date: Jul. 5, 2007

(54) Delay-locked loops for semiconductor devices and methods of controlling the same

(75) Inventors: Ji-Hyun Ahn, Jeonju-si (KR); Jae-Ki Yoo, Seoul (KR); Hye-In Choi, Yongin-si (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/635,042

(22) Filed: Dec. 7, 2006

(30) Foreign Application Priority Data
Jan. 2, 2006 (KR) 10-2006-0000069

(51) Int. Cl. H03L 7/06

(52) U.S. Cl. 327/158

(57) ABSTRACT

A delay-locked loop (DLL) circuit capable of decreasing power consumption is provided. A DLL circuit includes a delay line, an output buffer, a replica circuit, a phase detector, a shift register and a replica control circuit. The delay line delays an external clock signal for a determined time to generate a first signal. The output buffer buffers the first signal to generate an internal clock signal. The replica circuit delays the first signal for a determined time to generate a feedback signal. The phase detector compares the feedback signal with the external clock signal to generate a shift control signal. The shift register performs a shifting operation based on the shift control signal to generate the plurality of delay control bits. The replica control circuit generates a replica control signal based on the external clock signal and a lock signal, to control the replica circuit.

### PRIORITY STATEMENT

This non-provisional U.S. patent application claims priority under 35 USC §119 to Korean Patent Application No. 2006-0000069, filed on Jan. 2, 2006, in the Korean Intellectual Property Office (KIPO), the entire contents of which are incorporated herein by reference.

### BACKGROUND

### Description of the Conventional Art

Conventional delay-locked loops (DLL) may generate internal clock signals in conventional semiconductor integrated circuits. The conventional DLL may delay a system clock or an external clock signal to generate the internal clock signal. The DLL may detect a phase difference of the internal clock signal and the external clock signal, and control a delay using a shift operation, so that the internal clock signal is synchronized with the external clock signal.

In a conventional semiconductor integrated circuit such as a dynamic random-access memory (DRAM) device, the internal clock signal generated by the DLL may be used as a timing signal for operating a semiconductor memory device. For example, the internal clock signal may be used as a clock signal for outputting data from the semiconductor memory device or storing data in the semiconductor memory device.

Conventional semiconductor memory devices may include a plurality of memory cells for storing data. A write operation may be performed to store data in the memory cells, whereas a read operation may be performed to output data stored in the memory cells. Conventional write operations may include an active mode and a write mode. Conventional read operations may include an active mode and a read mode. In the active mode, the semiconductor memory device may activate an active command signal to activate memory cells for the read mode or the write mode. In the read mode, the semiconductor memory device may activate a read command signal and access the activated memory cells for reading stored data.

Current for activating memory cells in the active mode or accessing the memory cells in the read mode may be higher than normal current amounts so that a voltage level supplied to the semiconductor memory device may be decreased. When the voltage level supplied to the semiconductor memory device is decreased, a voltage level supplied to the DLL may change. When the voltage level supplied to the DLL changes, delay applied to the external clock signal may change. When the delay applied to the external clock signal changes, the external clock signal and the internal clock signal may become unsynchronized. When the external clock signal and the internal clock signal become unsynchronized, the DLL may perform a shift operation to control delay and/or compensate for voltage level decreases in the active mode. In this example, the internal clock signal may be synchronized with the external clock signal through the DLL.

FIG. 1 is a block diagram illustrating an example of a conventional DLL.

Referring to FIG. 1, a conventional DLL 100 may include a delay line 110, a phase detector 120, a shift register 130, a replica circuit 140 and an output buffer 150.

In example operation, the DLL 100 may receive an external clock signal XCLK through an input line 101 to generate an internal clock signal DLLCLK. The internal clock signal DLLCLK may be synchronized with the external clock signal XCLK. The delay line 110 may delay the external clock signal XCLK in response to delay control bits 104-1 through 104-N by as much as a determined delay amount. The delayed external clock signal may be provided to a node 106. The output buffer 150 may buffer an output signal of the delay line 110. The replica circuit 140 may receive the output signal from the delay line 110 through a line 105. The replica circuit 140 may delay the received output signal for a determined time. The replica circuit 140 may compensate for a delay time generated by the output buffer 150 and has the same or substantially the same delay as the delay generated by the output buffer 150.

The output signal of the delay line 110 may be fed back to the phase detector 120 through the replica circuit 140. A feedback signal CLKFB may be the same or substantially the same as the internal clock signal DLLCLK. The phase detector 120 may compare a phase of the feedback signal CLKFB with a phase of the external clock signal XCLK. When rising edges of the feedback signal CLKFB are not aligned (e.g., lined up) with rising edges of the external clock signal XCLK, the feedback signal CLKFB is not synchronized with the external clock signal XCLK. In this example, the phase detector 120 may activate a shift-left signal SL or a shift-right signal SR.

The shift register 130 may receive the shift-left signal SL or the shift-right signal SR through lines 102 or 103, respectively. The shift register 130 may perform a shift operation based on the shift-left signal SL or the shift-right signal SR to generate the delay control bits 104-1 through 104-N. The delay line 110 may control the delay of the external clock signal XCLK in response to the delay control bits 104-1 through 104-N to align rising edges of the internal clock signal DLLCLK and rising edges of the external clock signal XCLK.

When rising edges of the feedback signal CLKFB are aligned with rising edges of the external clock signal XCLK, the feedback signal CLKFB is synchronized with the external clock signal XCLK. In this case, the shift-left signal SL and the shift-right signal SR are disabled so that the shift register 130 discontinues the shift operation. For example, when the shift operation is discontinued, the DLL is in a lock mode, and the internal clock signal DLLCLK may be synchronized with the external clock signal XCLK.

In the conventional DLL of FIG. 1, the replica circuit 140 may remain on, even when the DLL is in the lock mode. As a result, power consumption may be unnecessarily increased.

### SUMMARY

Example embodiments relate to delay-locked loop circuits and methods of controlling the delay-locked loop, for example, a delay-locked loop circuit and a method of controlling the delay-locked loop of a semiconductor device.

At least some example embodiments provide delay-locked loop (DLL) circuits, which may decrease power consumption, for example, by adjusting a time during which a replica circuit is on.

At least some example embodiments provide semiconductor memory devices including a DLL circuit, which may decrease power consumption, for example, by adjusting a time during which a replica circuit is on.

At least some example embodiments provide a method of controlling a DLL circuit, which may decrease power consumption by adjusting a time during which a replica circuit is on.

In at least one example embodiment, a DLL circuit may include a delay line, an output buffer, a replica circuit, a phase detector, a shift register and/or a replica control circuit. The delay line may delay an external clock signal for a determined time in response to a plurality of delay control bits to generate a first signal. The output buffer may buffer the first signal to generate an internal clock signal. The replica circuit may delay the first signal for a determined time to generate a feedback signal. The phase detector may compare the external clock signal with the feedback signal to generate a shift control signal. The shift register may perform a shift operation based on the shift control signal to generate the plurality of delay control bits. The replica control circuit may generate a replica control signal based on the external clock signal and/or a lock signal to control the operation of the replica circuit.

In at least some example embodiments, the shift control signal may comprise a shift-left signal and shift-right signal. The replica circuit may delay the first signal for a delay time generated by the output buffer to generate the feedback signal. The replica circuit may not operate when the replica control signal is enabled. The replica control circuit may enable the replica control signal in response to the external clock signal when the lock signal is enabled. A frequency of the replica control signal may be lower than a frequency of the external clock signal. The replica control circuit may include a frequency divider, a flip-flop and/or a logic gate, such as an AND gate. The frequency divider may be configured to divide the external clock signal by a determined division ratio to generate a first pulse signal. The flip-flop may be configured to convert the first pulse signal to a second pulse signal. The second pulse signal may have a duty ratio of about 50:50. The logic gate may be configured to perform a logical AND operation between the lock signal and the second pulse signal to generate the replica control signal. The frequency divider may generate the first pulse signal by dividing the frequency of the external clock signal by about 3.

In at least some example embodiments, the DLL circuit may further include a duty cycle correction circuit configured to generate a second signal by modifying (e.g., correcting) a duty cycle of the first signal, which may be an output signal of the delay line. The DLL circuit may provide the second signal to the output buffer and the replica circuit. The duty cycle correction circuit may correct a duty ratio of the internal clock signal to be about 50:50 independent and/or regardless of a duty ratio of the external clock signal. For example, even though the duty ratio is not 50:50.

In example embodiments, a DLL circuit may include a delay line, an output buffer, a replica circuit, a frequency divider, a phase detector, a shift register and/or a replica control circuit. The delay line may delay an external clock signal in response to a plurality of delay control bits to generate a first signal. The output buffer may buffer the first signal to generate an internal clock signal. The replica circuit may delay the first signal for a determined time to generate a feedback signal. The frequency divider may divide the external clock signal by a determined division ratio to generate a first clock signal. The phase detector may compare the first clock signal with the feedback signal to generate a shift control signal. The shift register may perform a shift operation based on the shift control signal to generate the plurality of delay control bits. The replica control circuit may generate a replica control signal based on the first clock signal and a lock signal to control the operation of the replica circuit.

In example embodiments, the shift control signal may include a shift-left signal and a shift-right signal. The frequency divider may generate the first clock signal by dividing a frequency of the external clock signal by 3. The replica circuit may delay the first signal for a delay time generated by the output buffer to generate the feedback signal. The replica circuit may not operate when the replica control signal is enabled. The replica control circuit may enable the replica control signal in response to the external clock signal when the lock signal is enabled. A frequency of the replica control signal may be lower than a frequency of the external clock signal. The replica control circuit may include a flip-flop and a logic gate, such as a logical AND gate. The flip-flop may be configured to convert the first clock signal to a first pulse signal having a duty ratio of about 50:50, and the logic gate may be configured to perform a logical AND operation between the lock signal and the first pulse signal to generate the replica control signal.

In at least some example embodiments, the DLL circuit may further include a duty cycle correction circuit configured to generate a second signal by modifying (e.g., correcting) a duty cycle of the first signal, which may be an output signal of the delay line and may provide the second signal to the output buffer and the replica circuit. The duty cycle correction circuit may correct a duty ratio of the internal clock signal to be about 50:50, independent and/or regardless of a duty ratio of the external clock signal, for example, when even though the duty ratio of the external clock signal is not 50:50.

In example embodiments, a semiconductor memory device may include a DLL circuit and a replica control circuit. The DLL circuit may include a replica circuit and may generate an internal clock signal based on an external clock signal so that the internal clock signal may be synchronized with the external clock signal. The replica control circuit may turn the replica circuit on or off based on the external clock signal and a lock signal. The DLL circuit may include a delay line, an output buffer, the replica circuit, a phase detector and/or a shift register. The delay line may be configured to delay the external clock signal for a determined time in response to a plurality of delay control bits to generate a first signal. The output buffer may be configured to buffer the first signal to generate the internal clock signal. The replica circuit may be configured to delay the first signal for a determined time to generate a feedback signal. The phase detector may be configured to compare the external clock signal with the feedback signal to generate a shift control signal. The shift register may be configured to perform a shift operation based on the shift control signal to generate the plurality of delay control bits.

In at least some example embodiments, the shift control signal may include a shift-left signal and a shift-right signal. The replica circuit may delay the first signal for a delay time generated by the output buffer to generate the feedback signal. The replica circuit may not operate when the replica control signal is enabled. The replica control circuit may enable the replica control signal in response to the external clock signal when the lock signal is enabled. A frequency of the replica control signal may be lower than a frequency of the external clock signal. The DLL circuit may further include a duty cycle correction circuit configured to generate a second signal by modifying (e.g., correcting) a duty cycle of the first signal, which may be an output signal of the delay line, and provide the second signal to the output buffer and the replica circuit.

At least one example embodiment provides a method for controlling a DLL. According to at least this example embodiment, a first signal may be generated by delaying an external clock signal for a determined time in response to a plurality of delay control bits. An internal clock signal may be generated by buffering the first signal, and a feedback signal may be generated by delaying the first signal for a delay time generated during buffering of the first signal. A shift control signal may be generated by comparing the external clock signal with the feedback signal. The plurality of delay control bits may be generated by performing a shift operation based on the shift control signal. A replica control signal may be generated based on the external clock signal, and a lock signal may be generated to control the operation of the replica circuit.

In at least some example embodiments, the generating of the replica control signal may include generating a first pulse signal by dividing the external clock signal by a determined division ratio, converting the first pulse signal to a second pulse signal, of which a duty ratio may be about 50:50, and generating the replica control signal by performing a logic (e.g., a logical AND) operation with respect to the lock signal and the second pulse signal.

At least one other example embodiment provides a semiconductor memory device. The semiconductor memory device may include a DLL circuit, a row decoder, a column decoder, an input/output circuit, and/or a command decoder. The DLL circuit may include a replica circuit and may generate an internal clock signal based on an external clock signal so that the internal clock signal may be synchronized with the external clock signal. The replica control circuit may turn the replica circuit on or off based on the external clock signal and a lock signal. The row decoder may be configured to access rows of a memory cell array in response to externally applied addresses. The column decoder may be configured to access columns of the memory cell array in response to the externally applied addresses. The input/output circuit may be configured to output data or receive input data based on the internal clock signal generated by the circuit. The command decoder may be configured to receive a plurality of control signals to generate internal control signals by decoding the control signals.

### BRIEF DESCRIPTION OF THE DRAWINGS

Example embodiments will become more apparent by describing, in detail, the example embodiments shown in the attached drawings, wherein like elements are represented by like reference numerals, which are given by way of illustration only and thus do not limit the example embodiments.

FIG. 1 is a block diagram illustrating an example of a conventional delay-locked loop (DLL);

FIG. 2 is a block diagram illustrating a DLL, according to an example embodiment;

FIG. 3 is a circuit diagram illustrating an example embodiment of a replica control circuit, according to an example embodiment;

FIG. 4 is a timing diagram illustrating an example operation of the replica control circuit in FIG. 3;

FIG. 5 is a block diagram illustrating a DLL, according to another example embodiment;

FIG. 6 is a block diagram illustrating a DLL, according to another example embodiment;

FIG. 7 is a circuit diagram illustrating a replica control circuit, according to another example embodiment;

FIG. 8 is a block diagram illustrating a DLL, according to another example embodiment; and

FIG. 9 is a block diagram illustrating a semiconductor memory device, according to an example embodiment.

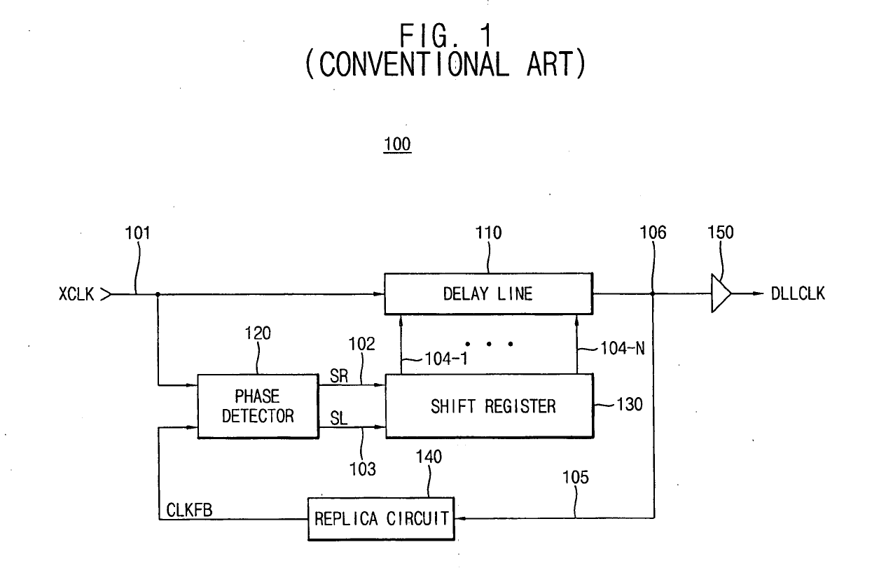

### DETAILED DESCRIPTION OF EXAMPLE EMBODIMENTS

Detailed illustrative example embodiments are disclosed herein. However, specific structural and functional details disclosed herein are merely representative for purposes of describing such example embodiments. The present invention may, however, be embodied in many alternate forms and should not be construed as limited to the example embodiments set forth herein.

Accordingly, while the present invention is susceptible to various modifications and alternative forms, specific example embodiments thereof are shown by way of example in the drawings and will herein be described in detail. It should be understood, however, that there is no intent to limit the present invention to the particular forms disclosed, but on the contrary, the present invention is to cover all modifications, equivalents, and alternatives falling within the spirit and scope of the present invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

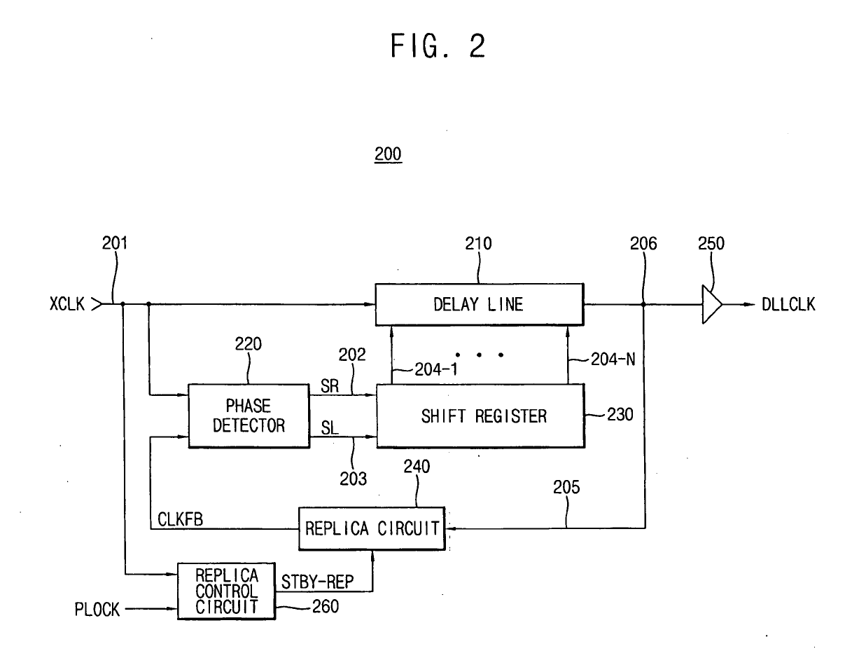

FIG. 2 is a block diagram illustrating a delay-locked loop (DLL), according to an example embodiment.

Referring to FIG. 2, a DLL 200 may include a delay line 210, an output buffer 250, a replica circuit 240, a phase detector 220, a shift register 230 and/or a replica control circuit 260. The delay line 210 may delay an external clock signal XCLK in response to delay control bits 204-1 through 204-N by as much as a determined delay amount. The delayed external clock signal XCLK may be provided to a node 206. The output buffer 250 may buffer an output signal of the delay line 210 to generate an internal clock signal DLLCLK. The replica circuit 240 may receive a signal of the node 206 (e.g., the output signal of the delay line 210) through a line 205 and may delay the signal of the node 206 for a delay time generated by the output buffer 250 to generate a feedback signal CLKFB. The phase detector 220 may compare a phase of the feedback signal CLKFB with a phase of the external clock signal XCLK to generate a shift-left signal SL or a shift-right signal SR. The shift register 230 may perform a shift operation based on the shift-left signal SL or the shift-right signal SR received from output terminals 202 and 203 of the phase detector 220 to generate the delay control bits 204-1 through 204-N. The replica control circuit 260 may generate a replica control signal STBY-REP based on the external clock signal XCLK and a lock signal PLOCK to control the operation of the replica circuit 240.

An example operation of the DLL 200 will be described with reference to FIG. 2. Referring to FIG. 2, in one example, the DLL 200 may receive the external clock signal XCLK through line 201 and generate the internal clock signal DLLCLK. The internal clock signal DLLCLK may be synchronized with the external clock signal XCLK. The replica circuit 240 may delay the output signal from the delay line 210 for a delay time generated by the output buffer 250 to generate a feedback signal CLKFB, which is the same or substantially the same as the internal clock signal DLLCLK. The DLL 200 may perform the shift operation based on the shift-left signal SL or the shift-right signal SR to generate the delay control bits 204-1 through 204-N. The delay line 210 may delay the external clock signal XCLK in response to the delay control bits 204-1 through 204-N by as much as a determined delay amount. The delay amount may be adjusted by the delay line 210 according to a value of the delay control bits 204-1 through 204-N. The shift-left signal SL and the shift-right signal SR may be generated by detecting a phase difference between the feedback signal CLKFB and the external clock signal XCLK in the phase detector 220. The phase detector 220 may be active when the phase of the feedback signal CLKFB is not aligned with the phase of the external clock signal XCLK. When an operating condition of the semiconductor memory device is changed, a phase difference may be generated. For example, when a supply voltage level is decreased in an active mode, a phase difference may be generated. When the decrease of the supply voltage level is detected, the DLL 200 may perform a shift operation to compensate for the decrease in supply voltage. In this example, the internal clock signal DLLCLK may be synchronized with the external clock signal XCLK by repeatedly detecting the phase difference and adjusting the delay amount accordingly. The output buffer 250 may include a path between an output terminal of the delay line 210 and a part using the internal clock signal DLLCLK.

As described above, the replica circuit 240 may compensate for the delay time due to the path between the output terminal of the delay line 210 and the part using the internal clock signal DLLCLK. While the internal clock signal DLLCLK is synchronized with the external clock signal XCLK, the replica circuit 240 may not operate. The DLL 200 in FIG. 2 may include the replica control circuit 260 to generate the replica control signal STBY-REP in response to the external clock signal XCLK when the lock signal PLOCK is enabled. When the replica control signal STBY-REP is enabled, the replica circuit 240 may not operate. While the internal clock signal DLLCLK is synchronized with the external clock signal XCLK, the replica circuit 240 may not operate and power consumption of the DLL 200 may decrease.

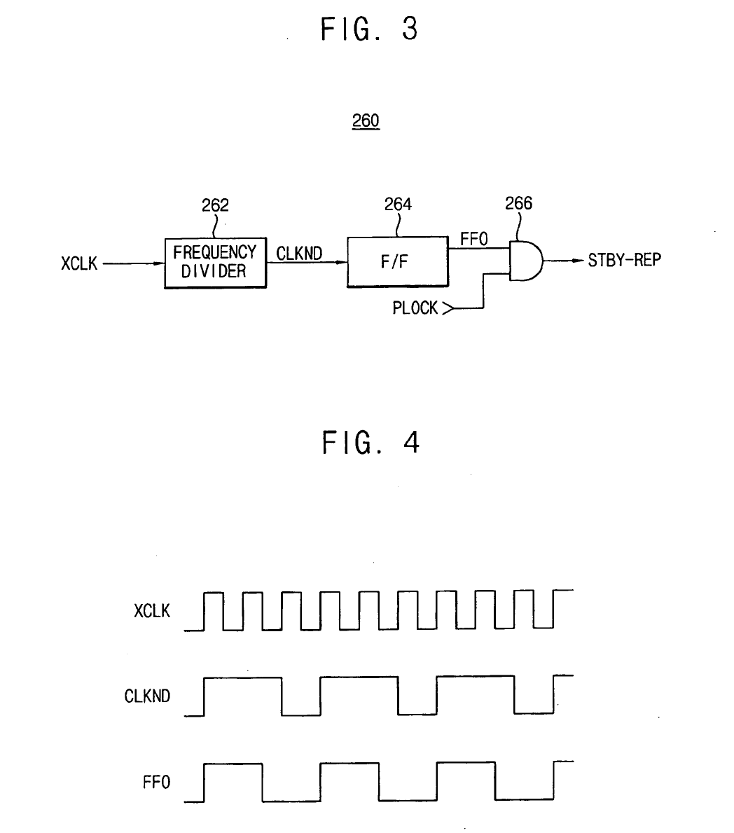

FIG. 3 is a circuit diagram illustrating a replica control circuit, according to an example embodiment. The replica control circuit of FIG. 3 may be included in the DLL of FIG. 2; however, alternatively the replica control circuit may be used in any conventional and/or related art DLL.

Referring to FIG. 3, a replica control circuit 260 may include a frequency divider 262, a flip-flop 264 and/or a logic gate (e.g., an AND gate) 266. Example embodiments will be described with regard to the logic gate 266 as an AND gate.

In example operation, the frequency divider 262 may divide the external clock signal XCLK by a determined division ratio to generate a pulse signal CLKND. The flip-flop 264 may convert the pulse signal CLKND to a pulse signal FFO in which a duty ratio may be about 50:50. The AND gate 266 may perform a logical AND operation between the lock signal PLOCK and the pulse signal FFO to generate the replica control signal STBY-REP.

FIG. 4 is a timing diagram illustrating an example operation of the replica control circuit of FIG. 3. The operation of the replica control circuit 260 included in the DLL 200 in FIG. 2 will be described with reference to FIG. 3 and FIG. 4.

The frequency divider 262 may divide the external clock signal XCLK by N to generate the pulse signal CLKND in which a frequency of the pulse signal CLKND may be lower than a frequency of the external clock signal XCLK. N may be a positive integer. In an output signal CLKND of the frequency divider 262, a logic “high” period may be different from a logic “low” period so that the flip-flop 264 may convert a duty ratio of the output signal CLKND of the frequency divider 262 to about 50:50. The AND gate 266 may perform a logical AND operation between the pulse signal FFO (e.g., the output signal of the flip-flop 264) and the lock signal PLOCK. The replica control signal STBY-REP, output from the replica control circuit 260, may be provided to the replica circuit 240 in FIG. 2.

FIG. 4 illustrates an example of generating the pulse signal CLKND by frequency dividing the external clock signal XCLK by 3. The pulse signal CLKND may have a frequency substantially equal to about ⅓ of a frequency of the external clock signal XCLK. In the pulse signal CLKND, a logic “high” period may be longer than a logic “low” period. The pulse signal FFO, which is the output signal of the flip-flop 264, may have the same or substantially the same period as the pulse signal CLKND and a duty ratio of about 50:50. The AND gate 266 in FIG. 3 may perform a logical AND operation between the pulse signal FFO and the lock signal PLOCK to generate the replica control signal STBY-REP.

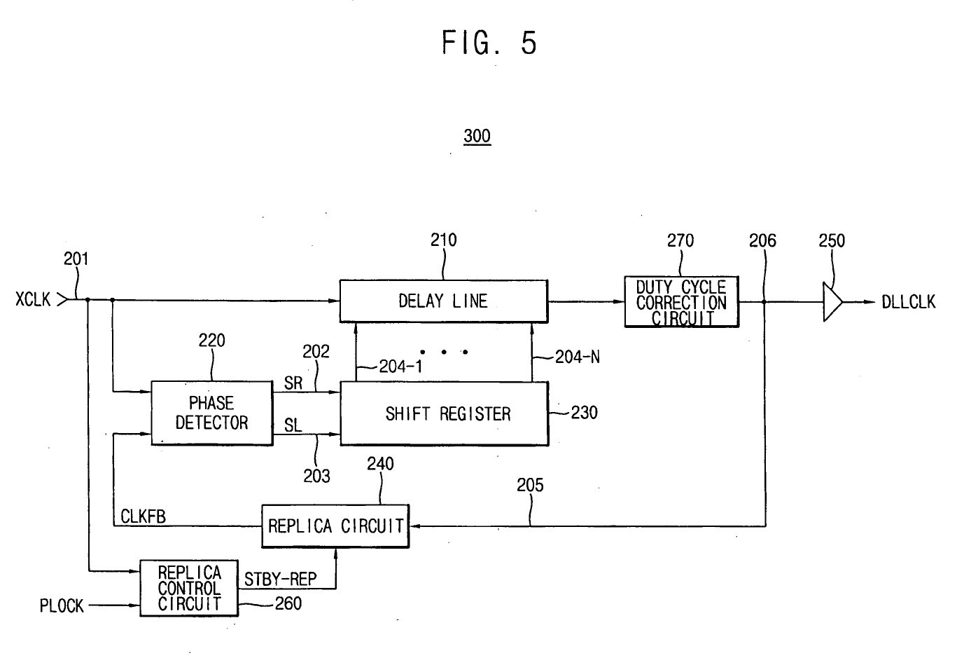

FIG. 5 is a block diagram illustrating a DLL, according to another example embodiment. The DLL 300 of FIG. 5 may be similar or substantially similar to the DLL 200 of FIG. 2, however, the DLL 300 may further include a duty cycle correction circuit 270. Referring to FIG. 5, a DLL 300 may include a delay line 210, an output buffer 250, a replica circuit 240, a phase detector 220, a shift register 230, a replica control circuit 260 and/or a duty cycle correction circuit 270.

The delay line 210 may delay an external clock signal XCLK by as much as a determined delay amount in response to delay control bits 204-1 through 204-N. The delayed external clock signal XCLK may be output to the duty cycle correction circuit 270. The duty cycle correction circuit 270 may modify (e.g., correct) a duty cycle of the delayed external clock signal XCLK. The output buffer 250 may buffer an output signal of the duty cycle correction circuit 270 to generate an internal clock signal DLLCLK. The replica circuit 240 may delay a signal of the node 206, which may also be the output signal from the duty cycle correction circuit 270. The replica circuit may delay the signal of the node 206 for a delay time generated by the output buffer 250 to generate a feedback signal CLKFB. The phase detector 220 may compare a phase of the feedback signal CLKFB with a phase of the external clock signal XCLK to generate a shift-left signal SL or a shift-right signal SR. The shift register 230 may perform a shift operation based on the shift-left signal SL or the shift-right signal SR to generate the delay control bits 204-1 through 204-N. The replica control circuit 260 may generate a replica control signal STBY-REP based on the external clock signal XCLK and a lock signal PLOCK to control the operation of the replica circuit 240.

An example operation of the DLL 300 in FIG. 5 will be described in more detail below. Because the DLL 300 of FIG. 5 may be similar or substantially similar to the DLL 200 of FIG. 2, a further description of the DLL 300 will be omitted for the sake of brevity.

In example operation, data may be output at rising edges and falling edges of the external clock signal XCLK in a double data rate (DDR) dynamic random-access memory (DRAM) device, and thus, bit periods of output data may be different from one another when a duty ratio of the external clock signal XCLK is not about 50:50. A valid data window may be determined by the relatively smallest one of the bit periods, so that when the bit periods of output data are different, a timing margin may be decreased. Therefore, the duty cycle of the external clock signal XCLK may be corrected.

When the duty cycle of the external clock signal XCLK is not about 50:50, the duty cycle correction circuit 270 may be included in the DLL 300 in FIG. 5. The duty cycle correction circuit 270 may control the duty ratio of the internal clock signal DLLCLK to be about 50:50. In this example, the bit period of the output data in the semiconductor memory device may be fixed and the timing margin of the memory system may be increased.

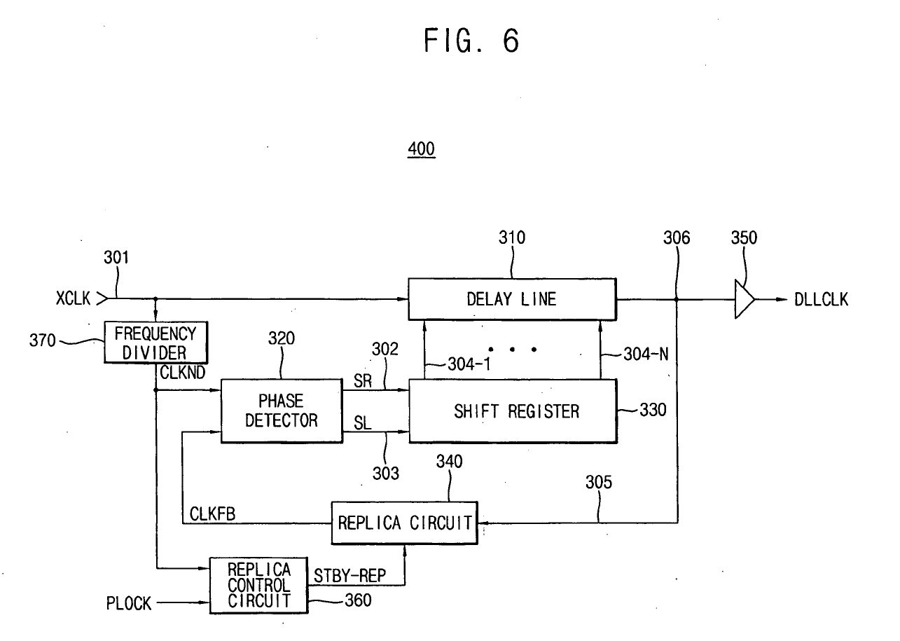

FIG. 6 is a block diagram illustrating a DLL, according to an example embodiment. The DLL 400 in FIG. 6 may be similar or substantially similar to the DLL 200 of FIG. 2, however, the DLL of FIG. 6 may further include a frequency divider 370. Referring to FIG. 6, a DLL400 may include a delay line 310, an output buffer 350, a replica circuit 340, a phase detector 320, a shift register 330, a replica control circuit 360 and/or the frequency divider 370.

The delay line 310 may delay an external clock signal XCLK, in response to delay control bits 304-1 through 304-N, for a determined time. The delayed external clock signal XCLK may be provided to a node 306. The output buffer 350 may buffer an output signal of the delay line 310 to generate an internal clock signal. The replica circuit 340 may delay a signal of the node 306, which may be an output signal of the delay line 310 for a delay time generated by the output buffer 350 to generate a feedback signal CLKFB. The frequency divider 370 may divide the external clock signal XCLK by a determined division ratio to generate a pulse signal CLKND. The phase detector 320 may compare the feedback signal CLKFB with the first clock signal CLKND to generate a shift-left signal SL or a shift-right signal SR. The shift register 330 may perform a shift operation based on the shift-left signal SL and the shift-right signal SR to generate the delay control bits 304-1 through 304-N. The replica control circuit 360 may generate a replica control signal STBY-REP based on the pulse signal CLKND and a lock signal PLOCK to control the operation of the replica circuit 340.

An example operation of the DLL 400 in FIG. 6 will be described in more detail below. The DLL 400 in FIG. 6 may include the frequency divider 370 for decreasing a frequency of the external clock signal XCLK to 1/N. The phase detector 320 may compare a phase of the feedback signal CLKFB with a phase of the pulse signal CLKND output from the frequency divider 370 to generate the shift-left signal SL or the shift-right signal SR. The shift-left signal SL and the shift-right signal SR may be generated by detecting a phase difference in the phase detector 320, and may be activated when the pulse signal CLKND and the feedback signal CLKFB are unsynchronized.

The DLL 400 of FIG. 6 may include replica control circuit 360 to generate the replica control signal STBY-REP in response to the pulse signal CLKND, output from the frequency divider 370, when the lock signal PLOCK is enabled. When the replica control signal STBY-REP is enabled, the replica circuit 340 may not operate. While the internal clock signal DLLCLK and the external clock signal XCLK are synchronized, the replica circuit 340 may not operate and power consumption of be the DLL 400 may decrease.

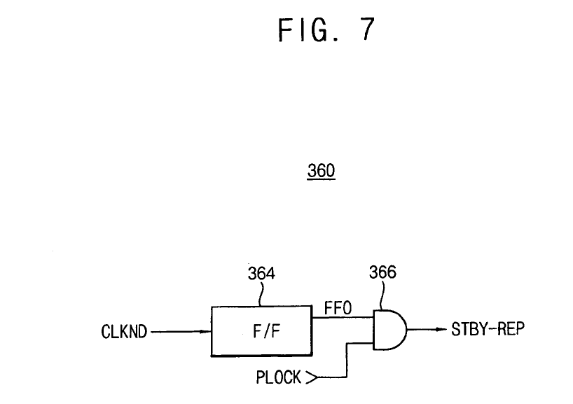

FIG. 7 is a circuit diagram illustrating a replica control circuit, according to an example embodiment. The replica control circuit of FIG. 7 may be included, for example, in the DLL in FIG. 6.

Referring to FIG. 7, a replica control circuit 360 may include a flip-flop 364 and/or a logic gate (e.g., an AND gate) 366. The flip-flop 364 may convert a duty ratio of a pulse signal CLKND to about 50:50 to generate a pulse signal FFO. The AND gate 366 may perform a logical AND operation between a lock signal PLOCK and the pulse signal FFO to generate a replica control signal STBY-REP.

A frequency of the pulse signal CLKND may be the same or substantially the same as 1/N of the external clock signal XCLK. In the pulse signal CLKND, a logic “high” period may be different from a logic “low” period. The pulse signal FFO, which may be an output signal of the flip-flop 364, has the same or substantially the same period as the pulse signal CLKND, but the duty ratio of the pulse signal FFO may be about 50:50. The AND gate 366 may perform an AND operation between the pulse signal FFO and a lock signal PLOCK to generate the replica control signal STBY-REP.

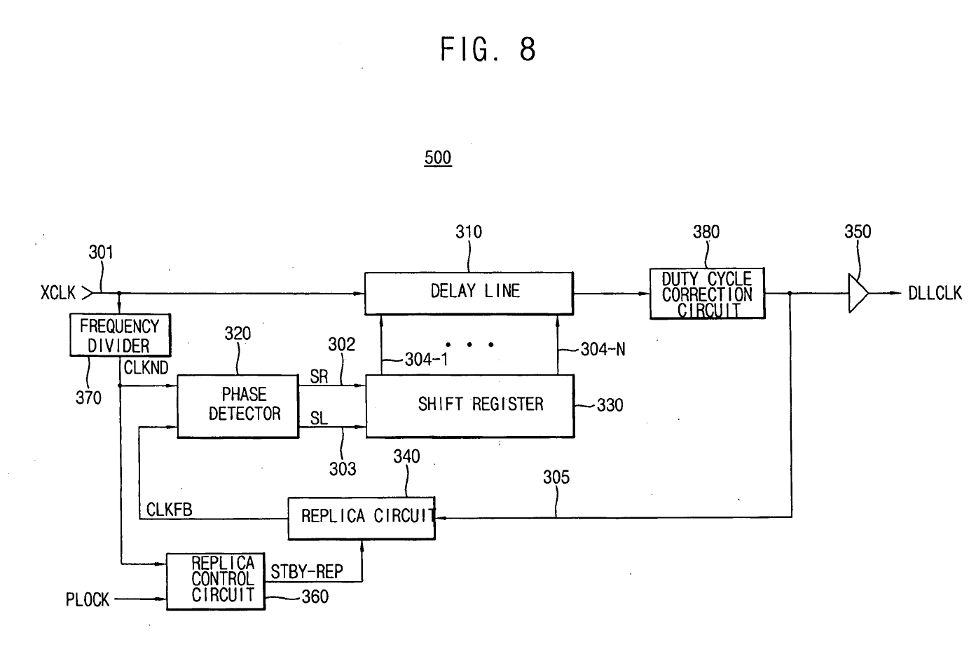

FIG. 8 is a block diagram illustrating a DLL, according to another example embodiment. The DLL 500 of FIG. 8 may be similar or substantially similar to the DLL 400 of FIG. 6, however, the DLL of FIG. 8 may further include a duty cycle correction circuit 380. Referring to FIG. 8, a DLL 500 may include a delay line 310, an output buffer 350, a replica circuit 340, a phase detector 320, a shift register 330, a replica control circuit 360, a frequency divider 370 and/or the duty cycle correction circuit 380.

The delay line 310 may delay an external clock signal XCLK in response to delay control bits 304-1 through 304-N. The duty cycle correction circuit 380 may modify (e.g., correct) a duty cycle of an output signal of the delay line 310. The output buffer 350 may buffer the output signal of the delay line 310 to generate an internal clock signal. The replica circuit 340 may delay a signal of a node 306, which may also be the signal output from the delay line 310, for a delay time generated by the output buffer 350, to generate a feedback signal CLKFB. The frequency divider 370 may divide the external clock signal XCLK by a determined division ratio to generate a first clock signal CLKND. The phase detector 320 may compare the feedback signal CLKFB with the first clock signal CLKND to generate a shift-left signal SL or a shift-right signal SR. The shift register 330 may perform a shift operation based on the shift-left signal SL or the shift-right signal SR to generate the delay control bits 304-1 through 304-N. The replica control circuit 360 may generate a replica control signal STBY-REP based on the first clock signal CLKND and a lock signal PLOCK to control the operation of the replica circuit 340.

The operation of the DLL 500 in FIG. 8 will be described in more detail below. In at least this example embodiment, the DLL 500 in FIG. 8 may be a circuit to which the duty cycle correction circuit 380 has been added. When a duty ratio of the external clock signal XCLK is not about 50:50, the duty cycle correction circuit 380 included in the DLL 500 in FIG. 8 may modify (e.g., correct) a duty ratio of the internal clock signal DLLCLK to about 50:50. Therefore, an output bit period of the semiconductor memory device may be fixed and the timing margin of the memory system may be increased.

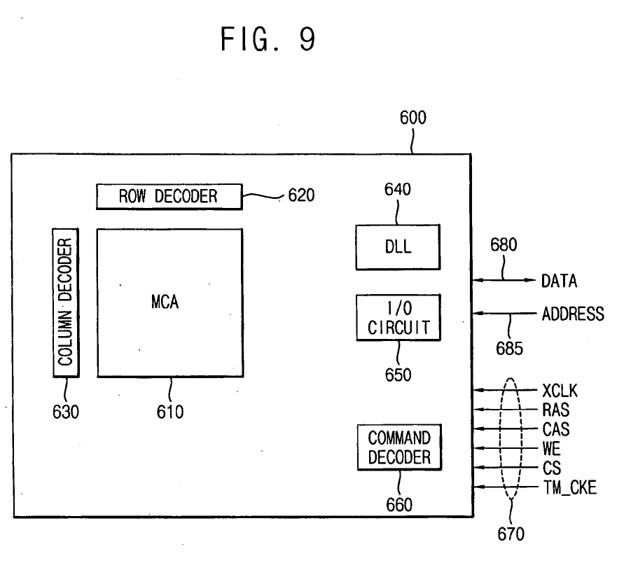

FIG. 9 is a block diagram illustrating a semiconductor memory device, according to an example embodiment. Referring to FIG. 9, a semiconductor memory device 600 may include a memory cell array 610, a row decoder 620, a column decoder 630, a DLL 640, an input/output (I/O) circuit 650 and/or a command decoder 660. The row decoder 620 and the column decoder 630 may access rows and columns of the memory cell array 610, respectively, in response to addresses provided via an address bus 685. Data may be transferred from the exterior to the semiconductor memory device 600 through the data bus 680. The I/O circuit 650 may cause data to be input from the exterior to the semiconductor memory device 600 or data to be output from the semiconductor memory device 600.

The command decoder 660 may receive control signals XCLK, RAS, CAS, WE, CS and TM_CKE from input lines 670 to generate internal control signals by decoding the control signals XCLK, RAS, CAS, WE, CS and TM_CKE. An operating mode of the semiconductor memory device, such as an active mode ACTIVE, a write mode WRITE, a read mode READ, a refresh mode REFRESH or the like may be determined according to the internal control signals. XCLK indicates an external clock signal, RAS indicates a row access strobe, CAS indicates a column access strobe, WE indicates a write enable, CS indicates a chip selection and TM_CKE indicates a test mode control signal. The DLL 640 may be any one of the DLLs shown in FIGS. 2, 5, 6 and/or 8. However, the example embodiment shown in FIG. 9 will be described with regard to the DLL of FIG. 2.

As shown in FIG. 2, the DLL 640 may generate shift control signals SL and SR based on the external clock signal XCLK and the feedback signal CLKFB. The DLL 640 may generate delay control bits 240-1 through 240-N based on the shift control signals SL or SR, and may cause an internal clock signal DLLCLK to be synchronized with the external clock signal XCLK by delaying the external clock signal XCLK for a determined time based on the delay control bits 240-1 through 240-N.

As described above, the DLL circuit, according to example embodiments, may include a replica control circuit, which may not operate while the internal clock signal is synchronized with the external clock signal thereby decreasing power consumption.

Although particular DLLs have been described as including particular replica control circuits, these replica control circuits are interchangeable within the DLLs. For example, the DLL of FIG. 2 may include either the replica control circuit of FIG. 3 or the replica control circuit of FIG. 7.

Example embodiments being thus described, the invention defined by the appended claims is not to be limited by particular details set forth in the above description as many apparent variations thereof are possible without departing from the spirit or scope thereof as hereinafter claimed.

What is claimed is:

1. A circuit comprising:
a delay locked loop (DLL) circuit including a replica circuit and being configured to generate an internal clock signal based on an external clock signal, the generated internal clock signal being synchronized with the external clock signal; and
a replica control circuit configured to control the replica circuit based on the external clock signal and a lock signal.

2. The circuit of claim 1, wherein the DLL circuit further includes:
a delay line configured to generate a first signal by delaying the external clock signal for a first time period in response to a plurality of delay control bits;
an output buffer configured to generate the internal clock signal by buffering the first signal;
a phase detector configured to generate a shift control signal based on a comparison between the external clock signal and a feedback signal generated from the replica circuit by delaying the first signal for a second time period; and
a shift register configured to generate the plurality of delay control bits by performing a shift operation based on the shift control signal, and
wherein the replica control circuit is configured to generate a replica control signal for controlling operation of the replica circuit, the replica control signal being generated based on the external clock signal and the lock signal.

3. The circuit of claim 2, wherein the shift control signal includes a shift-left signal and a shift-right signal.

4. The circuit of claim 2, wherein the replica circuit does not operate when the replica control signal is enabled.

5. The circuit of claim 2, wherein the replica control circuit enables the replica control signal in response to the external clock signal when the lock signal is enabled.

6. The circuit of claim 2, wherein a frequency of the replica control signal is lower than a frequency of the external clock signal.

7. The circuit of claim 2, wherein the replica control circuit includes,
a frequency divider configured to divide the external clock signal by a first division ratio to generate a first pulse signal,
a flip-flop configured to convert the first pulse signal to a second pulse signal having a duty ratio of about 50:50, and
a logic gate configured to generate the replica control signal by performing a logic operation between the lock signal and the second pulse signal.

8. The circuit of claim 7, wherein the frequency divider generates the first pulse signal by dividing the frequency of the external clock signal by 3.

9. The circuit of claim 2, wherein the DLL circuit further includes:
a duty cycle correction circuit configured to generate a second signal by modifying a duty cycle of the first signal, and configured to output the second signal to the output buffer and the replica circuit.

10. The circuit of claim 9, wherein the duty cycle correction circuit is configured to modify a duty ratio of the internal clock signal to be about 50:50 independent of the duty ratio of the external clock signal.

11. The circuit of claim 1, wherein the DLL circuit further includes:
a delay line configured to generate a first signal by delaying the external clock signal in response to a plurality of delay control bits,
an output buffer configured to generate the internal clock signal by buffering the first signal,
a frequency divider configured to generate a first clock signal by dividing the external clock signal by a first division ratio,
a phase detector configured to generate a shift control signal by comparing the first clock signal with a feedback signal generated from the replica circuit by delaying the first signal for a first time period, and
a shift register configured to generate the plurality of delay control bits by performing a shift operation based on the shift control signal, and
wherein the replica control circuit is configured to generate a replica control signal based on the first clock signal and the lock signal, the replica control signal controlling the operation of the replica circuit.

12. The circuit of claim 11, wherein the shift control signal includes a shift-left signal and a shift-right signal.

13. The circuit of claim 11, wherein the frequency divider generates the first clock signal by dividing a frequency of the external clock signal by 3.

14. The circuit of claim 11, wherein the replica circuit does not operate when the replica control signal is enabled.

15. The circuit of claim 11, wherein the replica control circuit enables the replica control signal in response to the external clock signal when the lock signal is enabled.

16. The circuit of claim 11, wherein a frequency of the replica control signal is lower than a frequency of the external clock signal.

17. The circuit of claim 11, wherein the replica control circuit includes,
a flip-flop configured to convert the first clock signal to a first pulse signal, the first pulse signal having a duty ratio of about 50:50, and
a logic gate configured to generate the replica control signal by performing a logic operation on the lock signal and the first pulse signal.

18. The circuit of claim 11, wherein the DLL circuit further includes:
a duty cycle correction circuit configured to generate a second signal by modifying a duty cycle of the first signal, and configured to output the second signal to the output buffer and the replica circuit.

19. The circuit of claim 18, wherein the duty cycle correction circuit is configured to modify a duty ratio of the internal clock signal to be about 50:50 independent of a duty ratio of the external clock signal.

20. A semiconductor memory device comprising:
the circuit of claim 1;
a row decoder configured to access rows of a memory cell array in response to externally applied addresses;
a column decoder configured to access columns of the memory cell array in response to the externally applied addresses;
an input/output circuit configured to output data or receive input data based on the internal clock signal; and
a command decoder configured to receive a plurality of control signals to generate internal control signals by decoding the control signals.

21. The semiconductor memory device of claim 20, wherein the DLL circuit further includes,
a delay line configured to generate a first signal by delaying the external clock signal for a first time period in response to a plurality of delay control bits,
an output buffer configured to generate the internal clock signal by buffering the first signal,
a phase detector configured to generate a shift control signal based on a comparison of the external clock signal and a feedback signal generated from the replica circuit by delaying the first signal for a second time period, and
a shift register configured to generate the plurality of delay control bits by performing a shift operation based on the shift control signal, and
wherein the replica control circuit is configured to generate a replica control signal based on the first clock signal and the lock signal, the replica control signal controlling the operation of the replica circuit.

22. The semiconductor memory device of claim 21, wherein the shift control signal includes a shift-left signal and a shift-right signal.

23. The semiconductor memory device of claim 21, wherein the replica circuit does not operate when the replica control signal is enabled.

24. The semiconductor memory device of claim 21, wherein a frequency of the replica control signal is lower than a frequency of the external clock signal.

25. The semiconductor memory device of claim 21, wherein the DLL circuit further includes,
a duty cycle correction circuit configured to generate a second signal by modifying a duty cycle of the first signal, and configured to output the second signal to the output buffer and the replica circuit.

26. The semiconductor memory device of claim 20, wherein the DLL circuit further includes,
a delay line configured to generate a first signal by delaying the external clock signal in response to a plurality of delay control bits,
an output buffer configured to generate the internal clock signal by buffering the first signal,
a frequency divider configured to generate a first clock signal by dividing the external clock signal by a first division ratio,
a phase detector configured to generate a shift control signal by comparing the first clock signal with a feedback signal generated from the replica circuit by delaying the first signal for a first time period, and
a shift register configured to generate the plurality of delay control bits by performing a shift operation based on the shift control signal, and
wherein the replica control circuit is configured to generate a replica control signal based on the first clock signal and the lock signal, the replica control signal controlling the operation of the replica circuit.

27. The semiconductor memory device of claim 26, wherein the DLL circuit further includes,
a duty cycle correction circuit configured to generate a second signal by modifying a duty cycle of the first signal, and configured to output the second signal to the output buffer and the replica circuit.

28. A method of controlling a delay locked loop, the method comprising:
generating a first signal by delaying an external clock signal for a first time period in response to a plurality of delay control bits;
generating an internal clock signal by buffering the first signal;
generating a feedback signal by delaying the first signal for a delay time, the delay time being generated during buffering of the first signal;
generating a shift control signal by comparing the external clock signal with the feedback signal;
generating the plurality of delay control bits by performing a shifting operation based on the shift control signal; and
generating a replica control signal based on the external clock signal and a lock signal to control the operation of the replica circuit.

29. The method of claim 28, wherein generating the replica control signal includes,
generating a first pulse signal by dividing the external clock signal by a first division ratio;
converting the first pulse signal to a second pulse signal, the second pulse signal having a duty ratio of about 50:50, and
generating the replica control signal by performing a logic operation on the lock signal and the second pulse signal.
